(19) United States
(12) Patent Application Publication
(10) Pub. No.: US 2016/0013136 A1
(43) Pub. Date: Jan. 14, 2016

(54) STRUCTURE AND METHOD FOR PROTECTING STRESS-SENSITIVE INTEGRATED CIRCUIT

(71) Applicant: QUALCOMM Incorporated, San Diego, CA (US)

(72) Inventors: Vidhya RAMACHANDRAN, San Diego, CA (US); Zhongping BAO, San Diego, CA (US)

(21) Appl. No.: 14/329,883

(22) Filed: Jul. 11, 2014

(51) Int. Cl. H01L 23/00; H01L 25/00; H01L 23/31; H01L 25/065

(52) U.S. Cl. CPC H01L 23/562; H01L 25/0657; H01L 25/50; H01L 23/3178; H01L 2225/06541; H01L 2225/06513; H01L 2225/06593

(57) ABSTRACT

Methods and apparatuses, wherein the method includes reducing stacking stress. The method couples a first die to a compliant layer. The method couples a second die to the compliant layer, wherein the compliant layer at least partially covers a portion of an interface between the first die and the second die, and wherein the compliant layer is formed in a trench in the second die.

### BACKGROUND OF THE INVENTION

1. Field of the Invention

Disclosed implementations relate to reducing stacking stress.

2. Description of the Related Art

Stress sensitive circuits can be impacted through the addition of dies. Keep-Out zones can be defined for regions of high stress, such as those under die edges or bumps Impact of stress may be included in the device models, so that sensitive circuits can be simulated with stress, allowing for improved design of sensitive circuits.

When a die or a package is stacked on top of another bare substrate, as is done in bare-die PoP or through-substrate stacking (TSS), the edge of a first die or package can be attached to a second die using a die attach material or an underfill material. During curing of this adhesive, the adhesive can shrink and cause stress to be applied on the back of the second die. This stress can be highest right at the edge of the underfill or die-attach layer, and can be transmitted through the second substrate. As substrates become thinner, a stressed region can come closer to a front side of the second die and can impact circuits in that area. This may not have as significant an impact on digital circuits, but some other circuits such as analog circuits are more stress sensitive and may cause IC failures.

FIG. 1 illustrates an exemplary die stack 100. In FIG. 1, the die stack 100 includes a first die 102, a second die 104, and a die attach 106 are shown. Regions with the highest stress can be measured around the areas where the second die 104 is coupled to the die attach 106. When stacking a die/package on top of a bare die (bare die PoP), the edge of the top die or package can exert stress on underlying substrate. When die attach material cures, it shrinks causing a stress at its edge. Stress region in bottom die can extend all the way to bottom die circuits, if bottom die is thin enough.

FIG. 2 illustrates an exemplary die stack 200. In FIG. 2, the die stack 200 includes a first die 202, a second die 204, a die attach 206 between the first die 202 and the second die 204, and sensitive circuits 208 coupled to a logic die 210. As shown, portions the sensitive circuits 208 are aligned with the areas where the second die 204 is coupled to the die attach 206. As stated in FIG. 1, this area can experience high stress. If this stress continues to the sensitive circuits 208, this stress can cause yield loss because of the sensitive circuits 208 being deformed in the portions aligned with the areas experiencing high stress.

### SUMMARY

The disclosure is directed to reducing stacking stress.

An apparatus can comprise a first die and a second die. The apparatus can comprise a compliant layer coupled to the first die and the second die, wherein the compliant layer at least partially covers a portion of an interface between the first die and the second die, and wherein the compliant layer is formed in a trench in the second die.

A method for reducing stacking stress, wherein the method can comprise coupling a first die to a compliant layer. The method can comprise coupling a second die to the compliant layer, wherein the compliant layer at least partially covers a portion of an interface between the first die and the second die, and wherein the compliant layer is formed in a trench in the second die.

An apparatus can comprise a first die. The apparatus can comprise a second die configured to provide an interconnect to the first die, wherein a sensitive circuit is coupled to an active face of the second die. The apparatus can comprise a compliant layer coupled to the first die and a non-active face of the second die, wherein the compliant layer at least partially covers a portion of an interface between the first die and the second die.

This can allow for less of the stress to be transmitted into the bottom substrate and disrupting the circuits on it. The die stack thickness can be unchanged so that the package size may not increase.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary die stack.

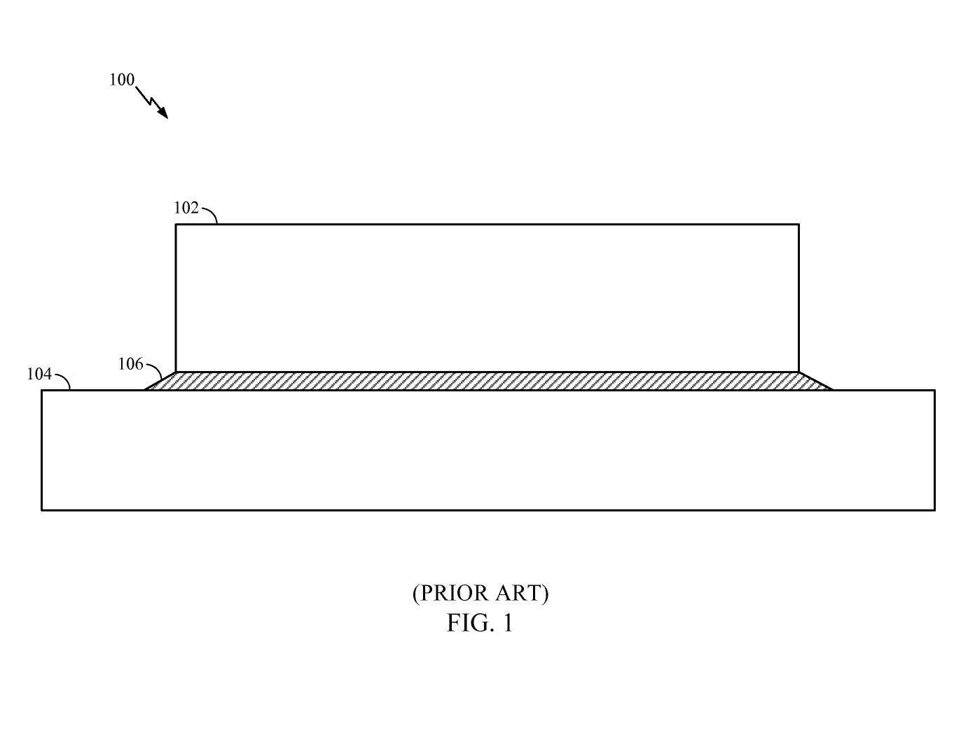

FIG. 2 illustrates an exemplary die stack.

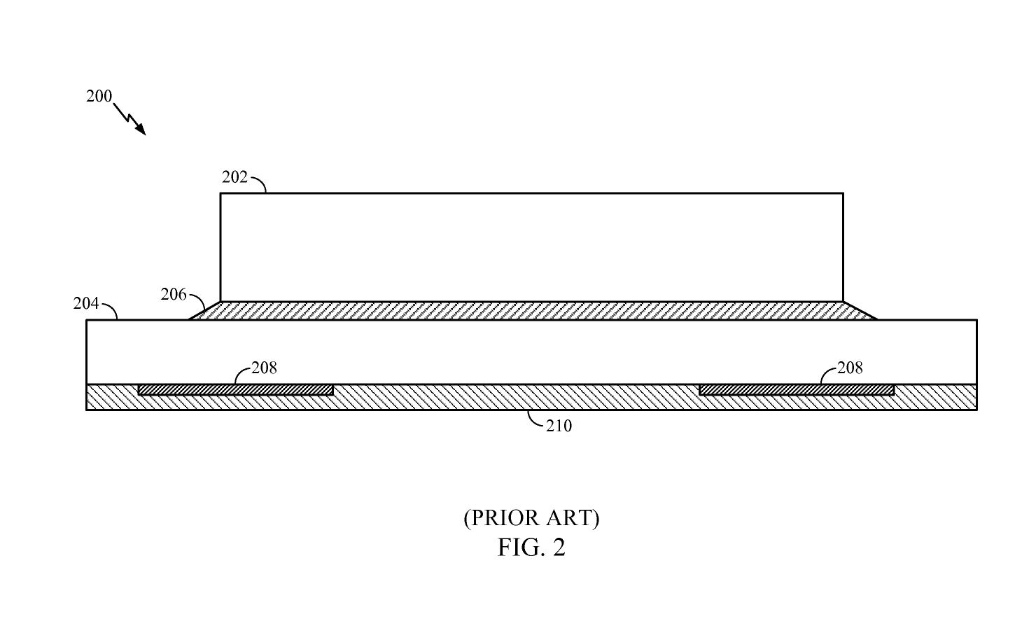

FIG. 3 illustrates an exemplary die stack with at least one compliant trench.

FIG. 4 illustrates an exemplary die stack with a compliant layer.

FIG. 5 illustrates an exemplary die stack with a compliant pad.

FIG. 6 illustrates an exemplary die stack.

FIG. 7 illustrates an exemplary die stack with a first die stacked on a second die.

FIG. 8 illustrates an exemplary die stack with a second die.

FIG. 9 illustrates simulation data comparing in-plane stress of a prior art die stack with a die stack with a compliant trench.

FIG. 10 illustrates simulation data comparing in-plane stress of a prior art die stack with a die stack with a compliant trench.

FIG. 11 illustrates an operational flow of a method.

### DETAILED DESCRIPTION

Various aspects are disclosed in the following description and related drawings. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

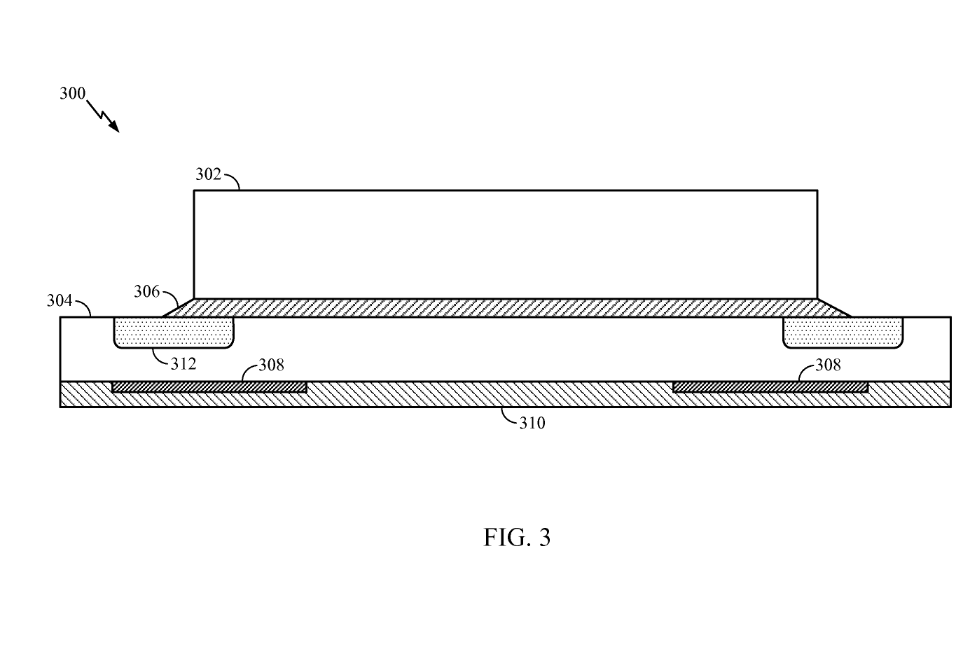

FIG. 3 illustrates an exemplary die stack 300 with at least one compliant trench. In FIG. 3, the die stack 300 includes a first die 302, a second die 304, a die attach 306 between the first die 302 and the second die 304, and sensitive circuits 308 coupled to a logic die 310. As shown, portions the sensitive circuits 308 and/or the the first die 302 edges are aligned with trenches 312 filled with compliant material.

In one embodiment, the trench of compliant material can be created underneath the first die edge. For example, a mask can be added to the process while the die thickness is approximately the same before and after the mask addition (i.e., the die thickness can be unchanged from an addition of a mask). In some implementations, the exemplary die stack 300 can be compatible with a 3D through die stacking type of process. In some embodiments, an integrated circuit can comprise the die stack 300.

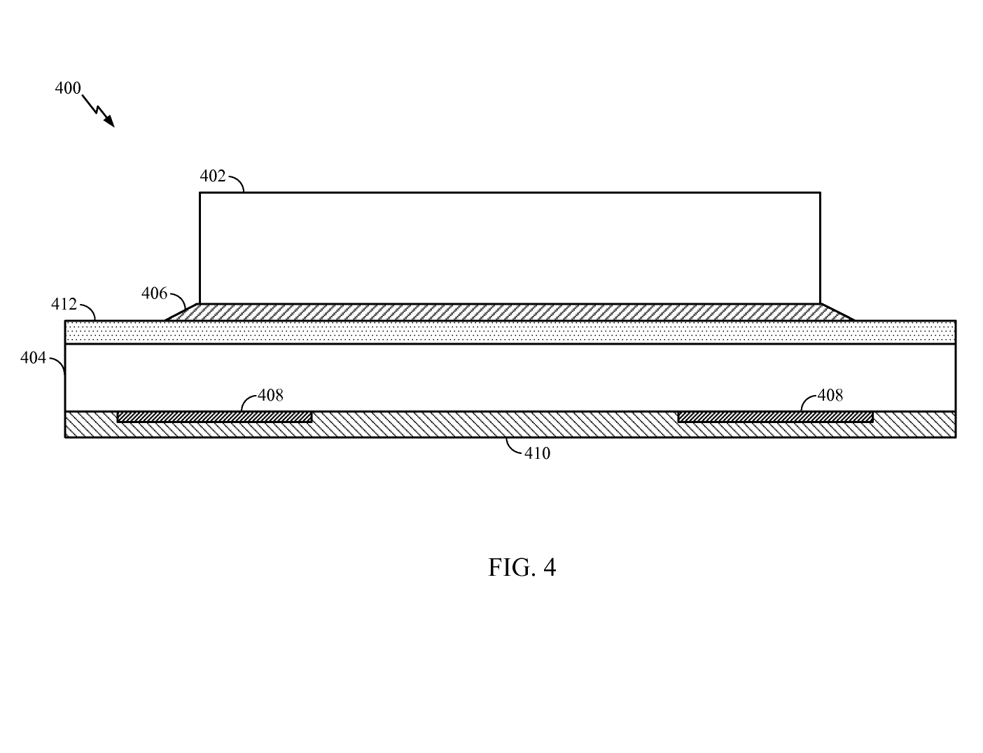

FIG. 4 illustrates an exemplary die stack 400 with a compliant layer 412. In FIG. 4, the die stack 400 includes a first die 402, a second die 404, a die-attach layer 406 between the first die 402 and the second die 404, and sensitive circuits 408 coupled to a logic die 410.

If the compliant layer 412 is placed on the back side of the second die 404 before the first die 402 is stacked on the second die 404, the compliant layer 412 can absorb some stress. Thus, less stress can be transmitted to the logic die 410 and sensitive circuits 408. In some implementations, the compliant layer 412 can be applied to back of a logic wafer after backside grinding has occurred. In some implementations, the overall die thickness can increase by an amount equal to a thickness of the compliant layer 412. In some embodiments, an integrated circuit can comprise the die stack 400.

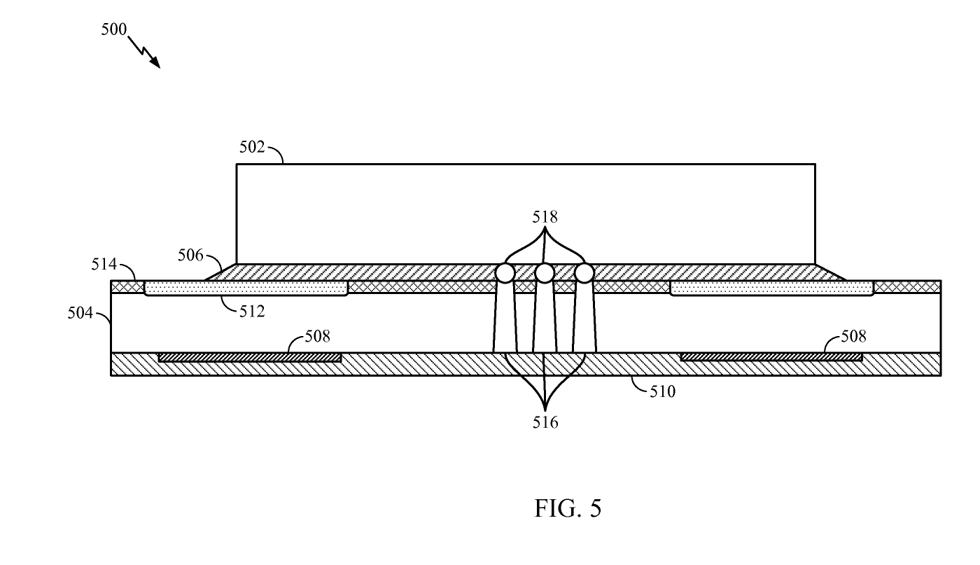

FIG. 5 illustrates an exemplary die stack 500 with a compliant pad 512. In FIG. 5, the die stack 500 includes a first die 502, a second die 504, an underfill 506 between the first die 502 and the second die 504, and sensitive circuits 508 coupled to a logic die 510. The compliant pad 512 can be embedded in the second die's 504 backside isolation 514. As shown in FIG. 5, the second die 504 can be comprised of through substrate vias 516. Each of these through substrate vias 516 is coupled to a u-bump 518. In FIG. 5, the u-bumps 518 are coupled to the underfill 506.

In some implementations, the compliant pad 512 can be a 3D-TSS compatible selective pad. In some implementations, the compliant pad 512 can have different configurations and positions. For example, the compliant pad 512 can lie behind the sensitive circuit block 508. The compliant pad 512 can lie underneath the first die 502 edge. The compliant pad 512 can be patterned into the backside isolation 514. In some embodiments, an integrated circuit can comprise the die stack 500.

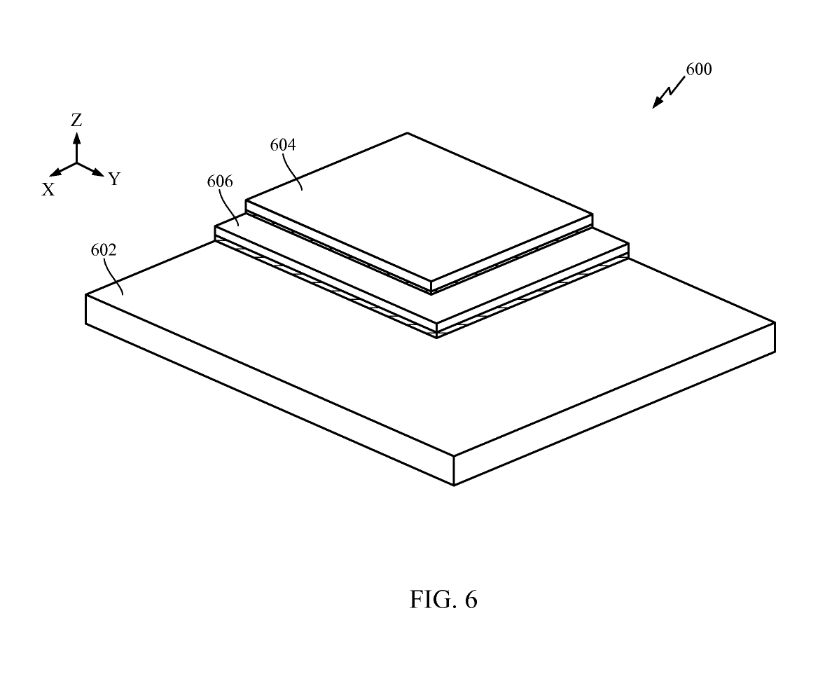

FIG. 6 illustrates an exemplary die stack 600 with non-limiting measurements. The die stack 600 has a substrate 602, a first die 604, and a second die 606. In FIG. 6, the substrate 602 is shown with measurements of 10 mm×10 mm×0.3 mm The first die 604 is shown with measurements of 5 mm×5 mm×0.1 mm The second die 606 is shown with measurements of 6 mm×6 mm×0.1 mm In some embodiments, a die attach can be implemented instead of a flip chip.

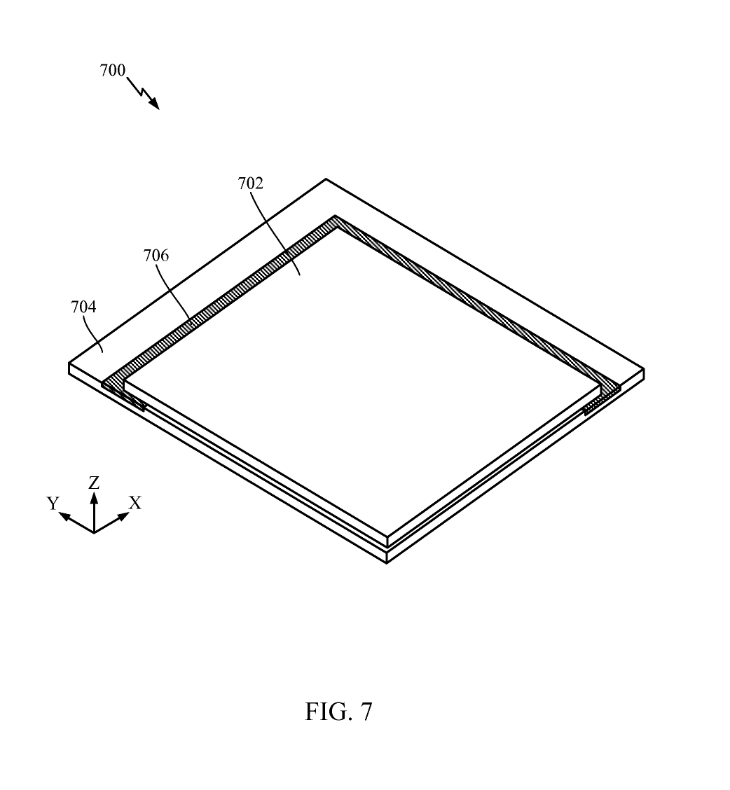

FIG. 7 illustrates an exemplary die stack 700 with a first die 702 stacked on a second die 704. A trench 706 is shown in the second die 704. In FIG. 7, the trench 706 is 30 um deep. The trench 706 can be filled with PI material.

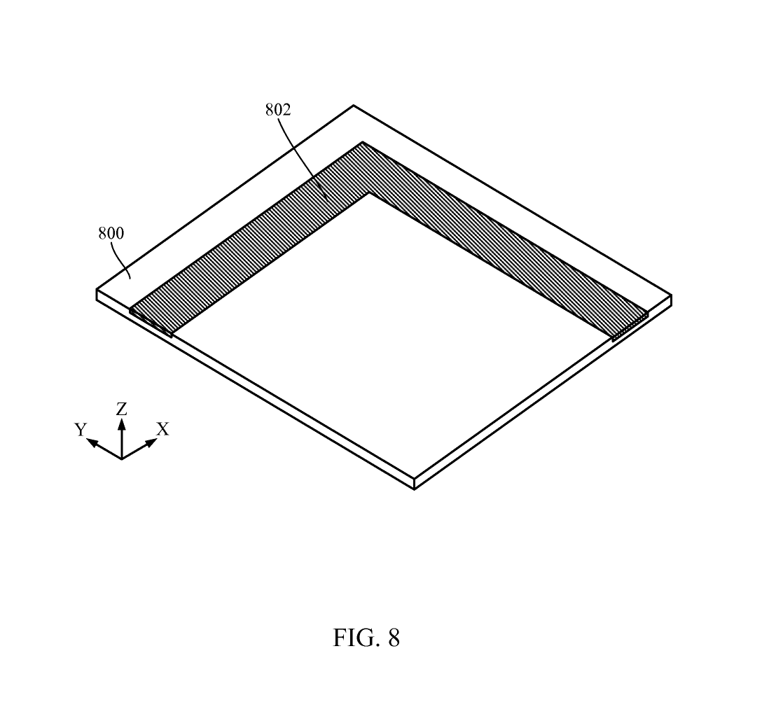

FIG. 8 illustrates an exemplary second die 800 with a trench 802.

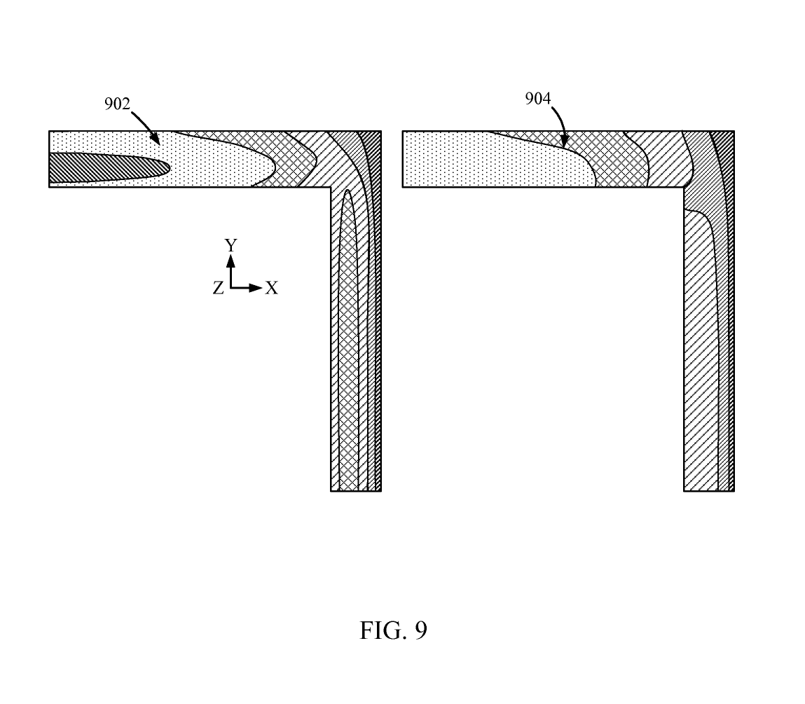

FIG. 9 shows simulation data comparing in-plane stress of a prior art die stack 902 with a die stack with a compliant trench 904. The shown areas represent an area in a second die below a trench in the die stack with a compliant trench 904 and the same area on the prior art die stack 902. As shown, the trench with the PI can reduce compressive in-plane stress by approximately seven percent. The data also shows that the trench with PI can reduce the area with large compressive in-plane stress

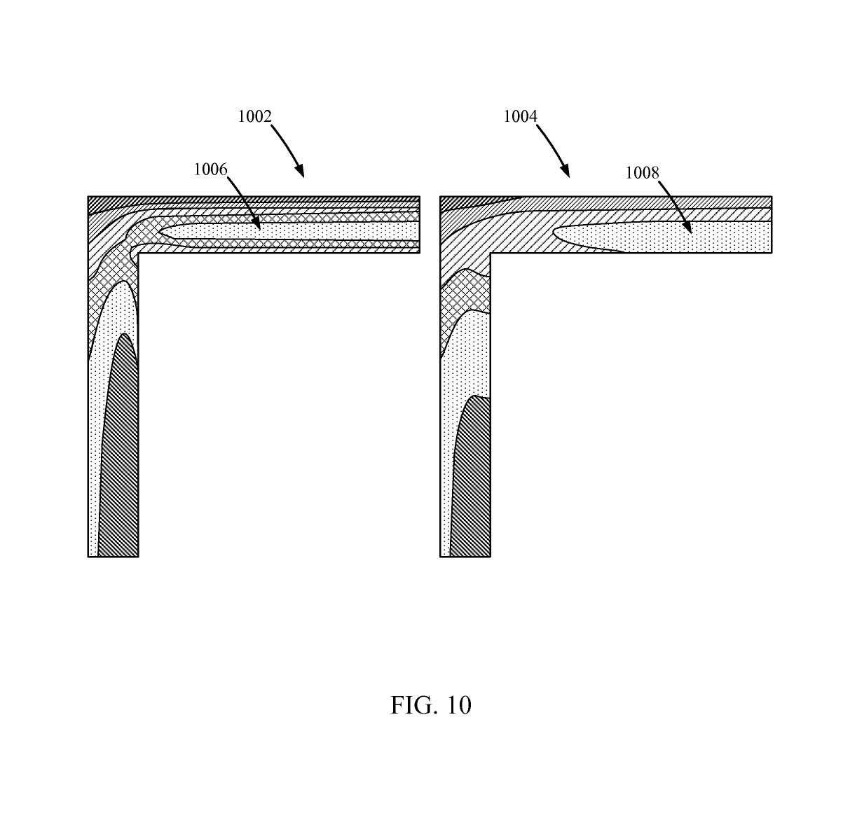

FIG. 10 shows simulation data comparing in-plane stress of a prior art die stack 1002 with a die stack with a compliant trench 1004. The regions 1006 and 1008 are regions of highest stress and it can be seen that these regions are reduced in extent in 1004.

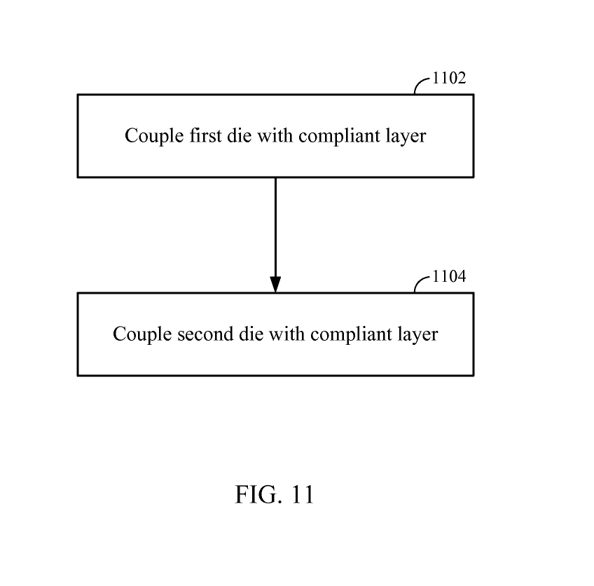

FIG. 11 illustrates an embodiment that can include a method comprising: coupling a first die to a compliant layer—Block 1102; and coupling a second die to the compliant layer, wherein the compliant layer at least partially covers a portion of an interface between the first die and the second die, and wherein the compliant layer is formed in a trench in the second die—Block 1104.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in an electronic object. In the alternative, the processor and the storage medium may reside as discrete components in a user terminal.

In one or more exemplary aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, DSL, or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes CD, laser disc, optical disc, DVD, floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An apparatus comprising:
a first die;
a second die; and
a compliant layer coupled to the first die and the second die, wherein the compliant layer at least partially covers a portion of an interface between the first die and the second die, and wherein the compliant layer is formed in a trench in the second die.

2. The apparatus of claim 1, wherein the compliant layer is formed in a trench in an isolation layer between the first die and the second die.

3. The apparatus of claim 1, wherein the second die is coupled to at least one of a substrate, interposer, or redistribution layer opposite to the first die.

4. The apparatus of claim 1, wherein the compliant layer is 3D through die stacking compatible.

5. The apparatus of claim 1, wherein die thickness is unchanged from an addition of a mask.

6. The apparatus of claim 1, wherein the second die comprises at least one through substrate via.

7. The apparatus of claim 6, wherein the at least one through substrate via is coupled to a u-bump.

8. The apparatus of claim 7, wherein the u-bump is coupled to an underfill.

9. The apparatus of claim 1, wherein the apparatus comprises an integrated circuit.

10. A method for reducing stacking stress, the method comprising:
coupling a first die to a compliant layer; and
coupling a second die to the compliant layer, wherein the compliant layer at least partially covers a portion of an interface between the first die and the second die, and wherein the compliant layer is formed in a trench in the second die.

11. The method of claim 10, wherein the compliant layer is formed in a trench in an isolation layer between the first die and the second die.

12. The method of claim 10, further comprising coupling the second die to at least one of a substrate, interposer, or redistribution layer opposite to the first die.

13. The method of claim 10, wherein the compliant layer is 3D through die stacking compatible.

14. The method of claim 10, wherein die thickness is unchanged from an addition of a mask.

15. The method of claim 10, wherein the second die comprises at least one through substrate via.

16. The method of claim 15, further comprising coupling the at least one through substrate via to a u-bump.

17. The method of claim 16, further comprising coupling the u-bump to an underfill.

18. An apparatus comprising:
a first die;
a second die configured to provide an interconnect to the first die, wherein a sensitive circuit is coupled to an active face of the second die; and
a compliant layer coupled to the first die and a non-active face of the second die, wherein the compliant layer at least partially covers a portion of an interface between the first die and the second die.

19. The apparatus of claim 18, wherein the compliant layer substantially covers the interface.

20. The apparatus of claim 18, wherein the compliant layer is formed in a trench in the second die.
